(19) United States
(12) Patent Application Publication
(10) Pub. No.: US 2025/0304756 A1
(43) Pub. Date: Oct. 2, 2025

(54) COMPOSITION, FILM, DISPLAY PANEL AND DISPLAY DEVICE

(71) Applicant: Shenzhen China Star Optoelectronics Semiconductor Display Technology Co., Ltd., Shenzhen (CN)

(72) Inventors: Xue BAI, Shenzhen (CN); Chengxiao SUN, Shenzhen (CN); Miao ZHOU, Shenzhen (CN); Lixuan CHEN, Shenzhen (CN); Chanjuan LIU, Shenzhen (CN); Xiaosa GAO, Shenzhen (CN); Aibing BAO, Shenzhen (CN); Miao DUAN, Shenzhen (CN); Qinfu ZHU, Shenzhen (CN)

(73) Assignee: Shenzhen China Star Optoelectronics Semiconductor Display Technology Co., Ltd., Shenzhen (CN)

(21) Appl. No.: 18/679,555

(22) Filed: May 31, 2024

(30) Foreign Application Priority Data
Mar. 29, 2024 (CN) 202410390351.1

(51) Int. Cl. C08J 5/18; C08K 3/36; C08L 33/14; H10K 50/125; H10K 77/10; H10K 85/10

(52) U.S. Cl. CPC C08J 5/18; C08K 3/36; C08L 33/14; H10K 50/125; H10K 77/10; H10K 85/10; C08J 2333/14

(57) ABSTRACT

The present disclosure relates to a composition, a film, a display panel and a display device. The composition includes, in parts by weight, the following ingredients: 50 parts to 100 parts of a resin matrix, 20 parts to 100 parts of a multifunctional reactive monomer, 1 part to 10 parts of an initiator, 5 parts to 30 parts of scattering particles; 100 parts to 500 parts of a solvent, and 1 part to 10 parts of additives. Each of the scattering particles has a mode diameter ranging from 500 nm to 5 μm. The film prepared by subjecting the composition to a thermo-curing treatment and/or a photo-curing treatment is used as the diffusion layer, which can ensure that the display panel has a good transmittance and resolution, effectively improve the chromaticity viewing angle of the display panel, and improve the problem of color shift of the large viewing angle.

### CROSS-REFERENCE TO RELATED APPLICATION

The present disclosure claims priority to and the benefit of Chinese Patent Application No. 202410390351.1, filed on Mar. 29, 2024, the disclosure of which is incorporated herein by reference in its entirety.

### TECHNICAL FIELD

The present disclosure relates to the field of display, and in particularly, to a composition, a film, a display panel, and a display device.

### BACKGROUND

In recent years, the proportion of the large-size display panels in the terminal market has been gradually increased. However, as the size of display panels gradually increases, the viewing angle range of the user is correspondingly increased. As a result, the problem of chromaticity distortion of the display panels caused by large viewing angle has gradually emerged.

As an example of the liquid crystal display panel, since there is a certain deflection angle between the liquid crystal and the normal of the panel under different gray scales, and there is a difference in And when light from different angles enters the liquid crystal, which leads to different brightness viewing angles at different gray levels, which in turn leads to significant color shift at large viewing angles. Currently, color shift is mainly improved by means of pixel design (e.g., multi-domain pixel structure), driving adjustment, and the like, but the transmittance and/or the resolution are often reduced, and the improvement method is complicated and the improvement effect is limited.

### SUMMARY

Embodiments of the present disclosure provide a composition, a film, a display panel, and a display device, so as to improve the problem of large viewing angle color shift of the display panel.

In a first aspect, embodiments of the present disclosure provide a composition, which includes, in parts by mass, the following ingredients:
50 parts to 100 parts of a resin matrix;
20 parts to 100 parts of a multifunctional reactive monomer;
1 part to 10 parts of an initiator;
5 parts to 30 parts of scattering particles;
100 parts to 500 parts of a solvent; and
1 part to 10 parts of additives;
wherein each of the scattering particles has a mode diameter ranging from 500 nm to 5 μm.

In a second aspect, the present disclosure provides a film prepared by subjecting the composition as described in the first aspect to a thermo-curing treatment and/or a photo-curing treatment.

In a third aspect, the present disclosure provides a display panel, which includes:
a light-emitting device layer comprising a light incident side and a light outgoing side oppositely disposed; and
a wide-viewing film disposed on the light outgoing side of the light-emitting device layer;
wherein the wide-viewing film comprises a diffusion layer, and the diffusion layer is the film as described in the second aspect.

In a fourth aspect, the present disclosure provides a display device, which incudes:
a display panel as described in the third aspect; and
a backlight disposed on the light incident side of the light-emitting device layer in the display panel.

Advantageous effects: in the composition provided according to embodiments of the present disclosure, the resin matrix, the multifunctional reactive monomer, the initiator, the scattering particles, the solvent and the additives are compounded in a specific ratio, and the mode diameter of the scattering particles ranges from 500 nm to 5 μm. As a result, on the one hand, the dispersion uniformity and the stability of the scattering particles in the composition are improved, and the problem of “settling” of the scattering particles is effectively improved, thereby improving the solution processing performance of the composition, and on the other hand, good scattering performance is imparted to the composition.

In the display panel provided in embodiments of the present disclosure, the film prepared by subjecting the composition to a thermo-curing treatment and/or a photo-curing treatment is used as the diffusion layer, which can improve the uniformity of the light at each viewing angle, ensure that the display panel has a good transmittance and resolution, effectively improve the chromaticity viewing angle of the display panel, improve the problem of color shift of the large viewing angle, and significantly improve the image quality perceived by human eyes.

### BRIEF DESCRIPTION OF THE DRAWINGS

In order to more clearly describe the technical solutions in embodiments of the present disclosure, the drawings used for describing the embodiments will be briefly introduced below. Apparently, the drawings described below are only directed to some embodiments of the present disclosure, and for a person with ordinary skills in the art, without expenditure of creative labor, other drawings can be derived on the basis of these drawings.

FIG. 1 is a schematic structural diagram of a film according to some embodiments of the present disclosure.

FIG. 2 is a schematic structural diagram of a display panel in a first construction according to some embodiments of the present disclosure.

FIG. 3 is a schematic structural diagram of a display panel in a second construction according to some embodiments of the present disclosure.

FIG. 4 is a schematic structural diagram of a display panel in a third construction according to some embodiments of the present disclosure.

FIG. 5 is a schematic structural diagram of a light-emitting device layer according to some embodiments of the present disclosure.

FIG. 6 is a schematic structural diagram of a display device according to some embodiments of the present disclosure.

FIG. 7 is an ultra-high resolution digital microscope photograph of the surface of the film in material example 11.

### LIST OF REFERENCE SIGNS

1: film, 10: display panel, 11: resin portion, 20: backlight, 100: display device, 101: light-emitting device layer, 102: first polarizer, 103: wide-viewing film, 104: polarizing film, 105: compensation film, 1012: second polarizer, 1013: array substrate, 1014: liquid crystal layer, 1015: color filter substrate, 1016: light incident side, 1011: light outgoing side, 1031: substrate layer, 1032: adhesive layer, 1033: diffusion layer.

### DETAILED DESCRIPTION

Hereinafter, technical solutions in embodiments of the present disclosure will be clearly and completely described with reference to the accompanying drawings in embodiments of the present disclosure. Apparently, the described embodiments are only part of, but not all of, the embodiments of the present disclosure. All the other embodiments, obtained by a person with ordinary skill in the art on the basis of the embodiments in the present disclosure without expenditure of creative labor, belong to the protection scope of the present disclosure.

Unless otherwise defined, all professional and scientific terms used herein have the same meaning as those familiar to those skilled in the art. In addition, any methods and materials similar or equivalent to those described herein can be applied to the present disclosure. The preferred embodiments and materials described are illustrative only and are not intended to be necessarily limiting.

It should be noted that the description order of the following embodiments is not intended to limit the preferred order of the embodiments. various embodiments of the present disclosure may be presented in a range format. It should be understood that the description in range format is merely for convenience and brevity and should not be construed as an inflexible limitation on the scope of the disclosure. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range. In addition, whenever a numerical range is indicated herein, it is meant to include any cited numeral (fractional or integral) within the indicated range.

The term “comprise/include” means “including but not limited to”.

The term “at least one” means one or more, and “a plurality” means two or more. The term “at least one”, “at least one of the following”, or the like, refers to any combination of these terms, including any combination of a single item or a plurality of items. For example, “at least one of a, b or c”; or “at least one of a, b, and c” can both be expressed as: a, b, c, a-b (i.e., a and b), a-c, b-c, or a-b-c, wherein a, b, and c may be single or a plurality, respectively.

The selection scope of the term “and/or” includes any one of two or more related listed items, as well as any and all combinations of related listed items, including any two related listed items, any more related listed items, or combinations of all related listed items. For example, “A and/or B” includes three parallel solutions A, B, and A +B. For another example, the technical solutions of “A, and/or, B, and/or, C, and/or, D” include any one of A, B, C, and D (i.e., the technical solutions are all connected by logic “or”), include any and all combinations of A, B, C, and D, that is, include any two or any three combinations of A, B, C, and D, and also include four combinations of A, B, C, and D (i.e., the technical solutions are all connected by logic “or”).

In the present disclosure, the term “mode diameter of the scattering particles” refers to the diameter of the scattering particles at which the frequency is at a maximum.

In the present disclosure, the term “mean particle size of the scattering particles” refers to the geometric mean particle size of the scattering particles.

Embodiments of the present disclosure provide a composition, which includes, in parts by weight, the following ingredients: 50 parts to 100 parts of a resin matrix; 20 parts to 100 parts of a multifunctional reactive monomer; 1 part to 10 parts of an initiator; 5 parts to 30 parts of scattering particles; 100 parts to 500 parts of a solvent and 1 part to 10 parts of additives; wherein each of the scattering particles has a mode diameter ranging from 500 nm to 5 μm, and the mode diameter of each of the scattering particles may be, for example, 500 nm, 1 μm, 2 μm, 3 μm, 4 μm, 5 μm or a value between any two of the above-mentioned values.

In the composition according to embodiments of the present disclosure, the resin matrix, the multifunctional reactive monomer, the initiator, the scattering particles, the solvent and the additives are compounded in a specific ratio, and the mode diameter of the scattering particles ranges from 500 nm to 5 μm. As a result, on the one hand, the dispersion uniformity and the stability of the scattering particles in the composition are improved, and the problem of “settling” of the scattering particles is effectively improved, thereby improving the solution processing performance of the composition, and on the other hand, good scattering performance is imparted to the composition.

In order to further improve the film-forming quality of the composition and enhance the scattering effect of the film formed by the composition, in some embodiments of the present disclosure, the ratio of a mass of the scattering particles to a sum of a mass of the resin matrix, the multifunctional reactive monomer, the initiator, and the scattering particles ranges from 10% to 30%, for example, it may range from 10% to 15%, 10% to 20%, or 15% to 25%, examples are 10%, 15%, 18%, 20%, 23%, 25%, 30%, or a value between any two of the aforementioned values.

In at least one embodiment of the present disclosure, the ratio of a mass of the scattering particles to a sum of a mass of the resin matrix, the multifunctional reactive monomer, the initiator, and the scattering particles ranges from 18% to 23%, which is beneficial to further improving the film-forming quality of the composition and enhancing the scattering effect of the film formed by the composition.

In order to ensure that the film formed by the composition has both good scattering effect and high transmittance, in some embodiments of the present disclosure, the refractive index of the scattering particles ranges from 1.3 to 1.7, for example, it can be 1.3, 1.35, 1.4, 1.5, 1.6, 1.7 or a value between any two of the aforementioned values.

In at least one embodiment of the present disclosure, the refractive index of the scattering particles ranges from 1.35 to 1.50, which is beneficial to further improving the scattering effect and the transmittance of the film formed by the composition.

In some embodiments of the present disclosure, the scattering particles are selected from one or more of inorganic scattering particles and/or the organic scattering particles, the inorganic scattering particles are selected from one or more of SiO₂, TiO₂, ZrO₂, Al₂O₃, and CaCO₃, and/or the organic scattering particles are selected from one or more of polystyrene, polymethyl methacrylate, and polybutyl methacrylate. The SiO₂ may be, for example, a gas-phase SiO₂.

In some embodiments of the present disclosure, the scattering particles are selected from spherical solid particles or mesoporous particles. The mesoporous particles are formed by aggregation of nanoscale particles. The average particle size of the scattering particles and/or an average particle size of an aggregate of the scattering particles ranges from 10 nm to 5 μm, for example, it can be 1 μm to 3 μm, and examples are 10 nm, 100 nm, 1 μm, 2 μm, and 3 μm, 4 μm, 5 μm or a value between any two of the aforementioned values. In this way, on the one hand, the dispersion uniformity and stability of the scattering particles can be further improved, thereby improving the film-forming quality of the composition; and on the other hand, the film formed by the composition has stronger scattering effect.

In the compositions according to embodiments of the present disclosure, the resin matrices are used as components of the main backbone. In some embodiments of the present disclosure, the refractive index of the resin matrix ranges from 1.3 to 1.7, for example, it can be 1.3, 1.35, 1.4, 1.5, 1.6, 1.7, or a value between any two of the foregoing values. It should be noted that the refractive index of the resin matrix and the refractive index of the scattering particles may be close to each other, for example, the absolute value of a difference between the refractive index of the resin matrix and the refractive index of the scattering particles is not more than 0.1, which can reduce the inner haze of the film formed by the composition.

In some embodiments of the present disclosure, the resin matrix is selected from one or more of acrylic resin, epoxy resin, and polyurethane resin.

In some embodiments of the present disclosure, the degree of polymerization of the resin matrix ranges from 10 to 100, for example, it may be 10, 30, 50, 80, 100, or a value between any two of the foregoing values; and/or, the weight average molecular weight of the resin matrix ranges from 1000 to 30000, for example, it may be 1000, 5000, 10000, 20000, 30000, or a value between any two of the foregoing values. It should be noted that in order to improve the mechanical properties of the film formed by the composition, it is necessary to use the resin matrices of oligomer and multifunctional reactive monomer to form a cross-linked network structure. In a case that the resin matrices in the composition are directly replaced by the cross-linked polymers, since the cross-linked polymers have high viscosity and are not easy to dissolve, which is not suitable for solution processing, resulting in poor film-forming quality.

Non-limiting examples of resin matrices are shown in Table 1 below:

TABLE 1

| | Product | |
|---|---|---|
| Name | model | Manufacturer |
| Polyurethane acrylate | CN996 NS | Sartomer (China) Co., Ltd. |
| oligomer | | |
| Polyester acrylate oligomer | CN2203 NS | Sartomer (China) Co., Ltd. |
| Epoxy acrylate oligomer | CN2003 NS | Sartomer (China) Co., Ltd. |
| Epoxy acrylate oligomer | CN115 NS | Sartomer (China) Co., Ltd. |
| Polyurethane acrylate | CN968 NS | Sartomer (China) Co., Ltd. |
| oligomer | | |
| Polyurethane acrylate | UT53956 | Guangzhou Wraio Chemical |
| oligomer | | Materials Co., Ltd. |
| Modified acrylic resin | UT95830 | Guangzhou Wraio Chemical |
| oligomer | | Materials Co., Ltd. |
| Polyurethane acrylate | FSP59369 | Guangzhou Wraio Chemical |
| oligomer | | Materials Co., Ltd. |
| Polyurethane acrylate | FSP2159 | Guangzhou Wraio Chemical |
| oligomer | | Materials Co., Ltd. |
| Polyurethane acrylate | FSP56392 | Guangzhou Wraio Chemical |
| oligomer | | Materials Co., Ltd. |

In some embodiments of the present disclosure, the multifunctional reactive monomer is selected from one or more of an acrylate monomer, an unsaturated olefin monomer, and an epoxy monomer.

Non-limiting examples of multifunctional reactive monomers are shown in Table 2 below:

TABLE 2

| Name | CAS number | Species |
|---|---|---|
| Dipentaerytritol hexaacrylate | 29570-58-9 | Acrylic monomer |
| Pentaerythritol triacrylate | 3524-68-3 | Acrylic monomer |
| Ditrimethylolpropane tetraacrylate | 94108-97-1 | Acrylic monomer |
| Isoboryl acrylate | 5888-33-5 | Acrylic monomer |
| 1,6-hexane diol diacrylate | 13048-33-4 | Acrylic monomer |
| Dodecyl vinyl ether | 765-14-0 | Unsaturated |
| | | olefin monomer |
| Octadecyl vinyl ethe | 930-02-9 | Unsaturated |
| | | olefin monomer |
| 1,4-cyclohexanedimethanol | 17351-75-6 | Unsaturated |
| divinyl ether | | olefin monomer |
| Dodecenyl succinic anhydride | 19780-11-1 | Unsaturated |
| | | olefin monomer |
| Triethylene glycol diglycidyl ether | 1954-28-5 | Epoxy monomer |
| Glycerol triglycidyl ether | 13236-02-7 | Epoxy monomer |
| Pentaerythritol tetraglycidyl ether | 3126-63-4 | Epoxy monomer |

In the compositions according to embodiments of the present disclosure, the initiator is used to initiate the reaction between the resin matrices and the multifunctional reactive monomers under light and/or heat conditions to form a cross-linked network structure. The initiator may be a common photoinitiator and/or thermal initiator, such as one or more of a peroxide initiator, an azo initiator, an acylphosphine oxide photoinitiator, and an amine initiator.

In some embodiments of the present disclosure, the peroxide initiator is selected from one or more of dibenzoyl peroxide (CAS No. 94-36-0), lauroyl peroxide (CAS No. 105-74-8), tert-butyl peroxybenzoate (CAS No. 614-45-9), tert-butyl peroxypentanoate (CAS No. 927-07-1), and t-hexyl peroxy-2-ethyl hexanoate (CAS No. 137791-98-1), and/or the azo initiator is selected from one or more of azobisisobutyronitrile (CAS No. 78-67-1) and azobisisoheptanenitrile (CAS No. 4419-11-8), and/or the acylphosphine oxide photoinitiator is selected from one or more of 2,4,6-(trimethylbenzoyl)-diphenylphosphine oxide (CAS No. 75980-60-8) and phenylbis (2,4,6-trimethylbenzoyl)-phosphine oxide (CAS No. 162881-26-7), and/or the amine initiator is selected from ethyl 4-dimethylaminobenzoate (CAS number 10287-53-3).

In some embodiments of the present disclosure, the additives are selected from one or more of leveling agents, defoaming agents, dispersants, antifouling additives, antioxidants, and ultraviolet absorbers.

Non-limiting examples of the additives are shown in Table 3 below:

TABLE 3

| Types of additives | Product model | Manufacturer/brand |
|---|---|---|
| Leveling agent | SF-337 | Guangzhou Wraio Chemical |
| | | Materials Co., Ltd. |
| Leveling agent | SF-729 | Guangzhou Wraio Chemical |
| | | Materials Co., Ltd. |
| Leveling agent | BYK-300 | Bike chemistry |
| Defoaming agent | SF-800 | Guangzhou Wraio Chemical |
| | | Materials Co., Ltd. |
| Dispersant | BYK-154 | BYK-Chemie |
| Dispersant | BYK-W 903 | BYK-Chemie |
| Dispersant | 7532 | AFCONA |
| Antifouling additive | BYK-342 | BYK-Chemie |
| Antifouling additive | BYK-337 | BYK-Chemie |
| Antifouling additive | BYK-333 | BYK-Chemie |
| Antioxidant | RIANOX 1010 | Tianjin Rianlon Corporation |
| Antioxidant | RIANOX 1076 | Tianjin Rianlon Corporation |
| Ultraviolet absorber | RIASORB UV-326 | Tianjin Rianlon Corporation |
| Ultraviolet absorber | RIASORB UV-329 | Tianjin Rianlon Corporation |

In some embodiments of the present disclosure, the solvent is selected from one or more of an ester compound, a ketone compound, an alcohol compound, and an ether compound. The ester compound has a general structure of R₉COOR₁₀, and R₉ and R₁₀ are each independently selected from C1 to C10 alkyl group, C1 to C6 alkyl group, or C1 to C4 alkyl group. For example, the ester compound is selected from one or more of ethyl acetate, methyl acetate, ethyl formate, and propyl acetate. The ketone compound has a general structure of R₁₁COOR₁₂, and R₁₁ and R₁₂ are each independently selected from C1 to C10 alkyl group, C1 to C6 alkyl group, or C1 to C4 alkyl group. For example, the ketone compound is selected from one or more of acetone, methyl isobutyl ketone, and butanone. The alcohol compound has a general structure of R₁₃OH, and R₁₃ is selected from one or more of an unsubstituted C1 to C10 alkyl group, a hydroxy-substituted C1 to C10 alkyl group, an unsubstituted C1 to C6 alkyl group, a hydroxy-substituted C1 to C6 alkyl group, an unsubstituted C1 to C4 alkyl group, or a hydroxy-substituted C1 to C4 alkyl group. For example, the alcohol compound is selected from one or more of methanol, ethanol, propanol, butanol, and pentanol. The ether compound has a general structure of R₁₄OR₁₅, and R₁₄ and R₁₅ are each independently selected from C1 to C10 alkyl group, C1 to C6 alkyl group, or C1 to C4 alkyl group. For example, the ether compound is selected from one or more of methyl ether, ethyl ether, propyl ether, butyl ether, and pentyl ether.

Embodiments of the present disclosure further provide a film prepared by subjecting the composition as described in any one of the foregoing to a thermo-curing treatment and/or a photo-curing treatment. It can be understood that the material of the film includes a network structure formed by cross-linking resin matrices and multifunctional reactive monomers.

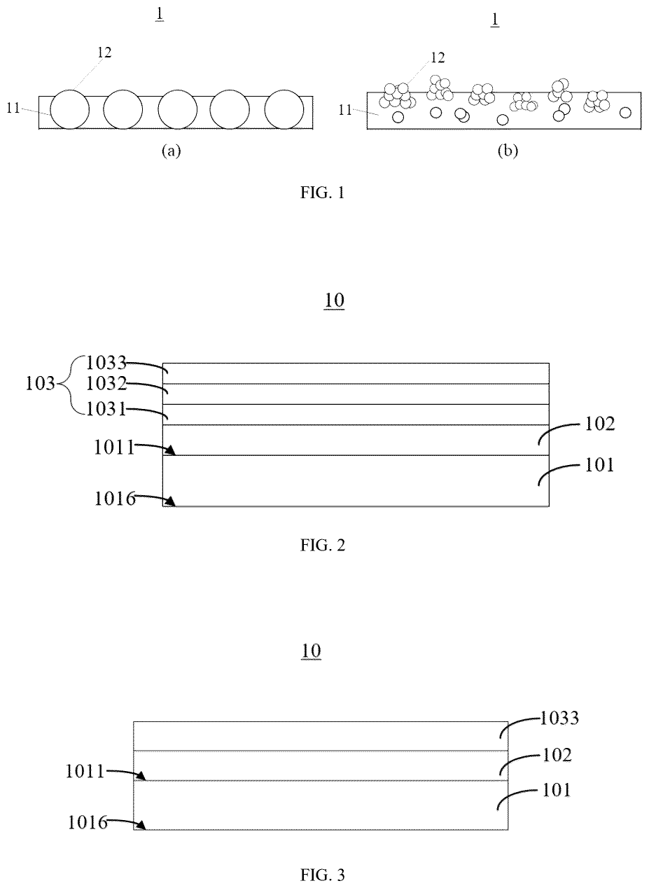

In some embodiments of the present disclosure, as shown in FIG. 1, the film 1 includes a resin portion 11, and at least a part of the scattering particles 12 protrudes from a surface of the resin portion 11, so that the surface of the film 1 has a convex structure. The convex structure can refract transmitted light, thereby achieving the effect of light mixing. The scattering particles 12 shown in FIG. 1(a) have a microsphere structure, and the scattering particles 12 shown in FIG. 1(b) have a mesoporous structure.

In some embodiments of the present disclosure, the average thickness of the film 1 ranges from 1 μm to 5 μm, for example, it may be 1 μm, 2 μm, 3 μm, 4 μm, 5 μm, or a value between any two of the aforementioned values.

In some embodiments of the present disclosure, the mass of the scattering particles 12 accounts for 10% to 30% of the total mass of the film 1, for example, 10%, 15%, 18%, 20%, 23%, 25%, 30% or a value between any two of the aforementioned values. Alternatively, the mass of the scattering particles 12 accounts for 18% to 23% of the total mass of the film 1, so as to ensure that the film has good scattering effect.

In some embodiments of the present disclosure, the method for preparing the film 1 includes, for example, the steps of providing a substrate, depositing a composition on one side of the substrate, and then subjecting the deposited composition to a thermo-curing treatment and/or a photo-curing treatment to obtain a film.

The deposition method of the composition may be, for example, a solution method including, but not limited to, one or more of spin-coating, printing, ink jet printing, scrape coating, dip-coating, soaking, spraying, roller-coating, casting, slot die coating and strip coating. The temperature of the thermo-curing treatment may be, for example, 50° C. to 120° C., and the photo-curing treatment may be, for example, achieved by using ultraviolet light.

Embodiments of the present disclosure further provide a display panel. As shown in FIGS. 2 to 4, the display panel 10 includes a light-emitting device layer 101 and a wide-viewing film 103. The light-emitting device layer 101 includes a light incident side 1016 and a light outgoing side 1011 that are oppositely disposed. The wide-viewing film 103 includes a diffusion layer 1033, which is any one of the films described above. The light-emitting device layer 101 includes a plurality of pixels distributed in an array, each pixel includes at least three sub-pixels with different primary colors, and each pixel is composed of, for example, a red sub-pixel, a blue sub-pixel and a green sub-pixel.

In the display panel 10 according to embodiments of the present disclosure, any of the films mentioned above is used as the diffusion layer, which can improve the uniformity of light at each viewing angle, ensure that the display panel has a good transmittance and resolution, effectively improve the chromaticity viewing angle of the display panel, and improve the problem of color shift of the large viewing angle.

In some embodiments of the present disclosure, referring to FIGS. 2 and 3, the display panel 10 further includes a first polarizer 102 disposed between the light-emitting device layer 101 and the wide-viewing film 103. The first polarizer 102 may have a conventional structure in the art, including, for example, an adhesive layer, a compensation film, a polarizing film, and a protective layer disposed sequentially. The adhesive layer is closer to the light-emitting device layer 101 than the protective layer. The material of the adhesive layer includes but is not limited to one or more of a heat-sensitive adhesive, a pressure-sensitive adhesive, and an ultraviolet curable adhesive. The material of the compensation film includes but is not limited to one or more of polyethylene terephthalate (PET), tri-cellulose acetate (TCA), cyclo olefin polymer (COP), polycarbonate (PC), and polymethyl methacrylate (PMMA). The material of the polarizing film includes but is not limited to one or more of polyvinyl alcohol (PVA). The material of the protective layer includes but is not limited to one or more of PET, TCA, COP, and PMMA. The first polarizer 102 may also not include a compensation film.

In order to improve the mechanical properties of the wide-viewing film 103, in at least one embodiment of the present disclosure, referring to FIG. 2, the wide-viewing film 103 further includes a substrate layer 1031 disposed on one side of the diffusion layer 1033 close to the light-emitting device layer 101. The substrate layer 1031 is selected from transparent polymers such as one or more selected from PET, TCA, COP, and PMMA. Continuing to refer to FIG. 2, the substrate layer 1031 may be bonded to one side of the light-emitting device layer 101 by an adhesive layer 1032. The material of the adhesive layer 1032 includes, but is not limited to, one or more of a heat-sensitive adhesive, a pressure-sensitive adhesive, and an ultraviolet curable adhesive.

In order to simplify the preparation process of the display panel 10, in at least one embodiment of the present disclosure, continuing to refer to FIG. 3, and the wide-viewing film 103 is a diffusion layer 1033.

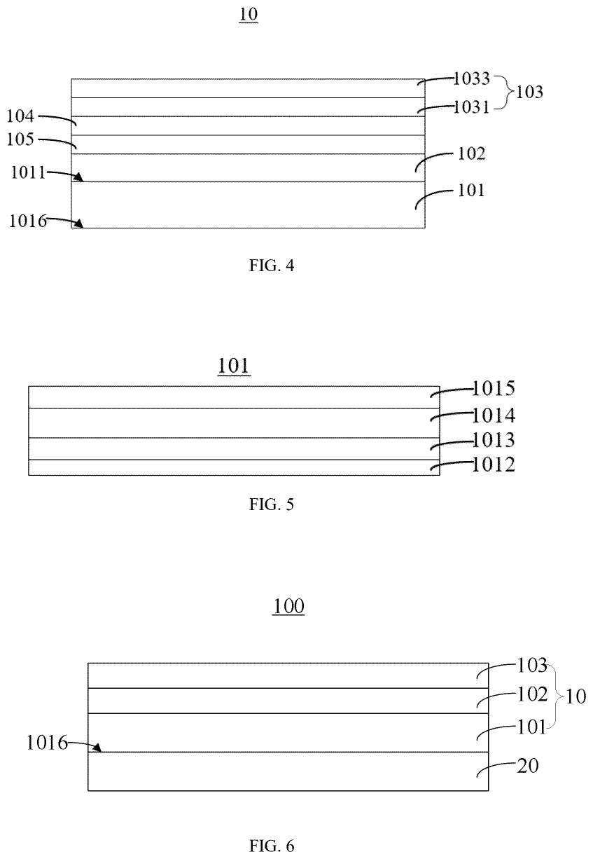

In still other embodiments of the present disclosure, continuing to refer to FIG. 4, the display panel 10 further includes a polarizing film 104 and a and a compensation film 105 that are stacked. The polarizing film 104 is disposed between the light-emitting device layer 101 and the wide-viewing film 103. The compensation film 105 is disposed on one side of the polarizing film 104 away from the wide-viewing film 103. The polarizing film 104 may be bonded to one side of the light-emitting device layer 101 by one or more of a heat-sensitive adhesive, a pressure-sensitive adhesive, and an ultraviolet curing adhesive. The polarizing film 104 and the compensation film 105 may also be bonded to each other by one or more of a heat-sensitive adhesive, a pressure-sensitive adhesive, and an ultraviolet curing adhesive. The wide-viewing film 103 is composed of, for example, a substrate layer 1031 and a diffusion layer 1033 that are stacked. The materials of the polarizing film 104 and the compensation film 105 may refer to the above description.

In some embodiments of the present disclosure, as shown in FIG. 5, the display panel is a liquid crystal display panel. The light-emitting device layer 101 includes a second polarizer 1012, an array substrate 1013, a liquid crystal layer 1014, and a color filter substrate 1015. The array substrate 1013 and the color filter substrate 1015 are oppositely disposed and are respectively disposed on both sides of the liquid crystal layer 1014. The second polarizer 1012 is disposed on one side of the array substrate 1013 away from the liquid crystal layer 1014. It should be noted that the wide-viewing film 103 is disposed on one side of the first polarizer 102 away from the color filter substrate 1015. The structural composition of the second polarizer 1012 refers to the description of the first polarizer 102. The array substrate 1013, the liquid crystal layer 1014, and the color filter substrate 1015 may be common structures in the art. The display mode of the liquid crystal display panel in embodiments of the present disclosure includes, but is not limited to, twisted nematic (TN), in-plane-switching (IPS), or vertical alignment (VA).

In some embodiments of the present disclosure, the display panel has a multi-domain pixel structure, such as a four-domain pixel structure or an eight-domain pixel structure.

In other embodiments of the present disclosure, the light-emitting device layer 101 includes a plurality of light-emitting diodes disposed in an array, and the light-emitting diodes include but are not limited to organic electroluminescent diodes or quantum dot light-emitting diodes.

Embodiments of the present disclosure further provides a display device. As shown in FIG. 6, the display device 100 includes a display panel 10 and a backlight 20. The display panel 10 may be any one of the above-mentioned display panels. The backlight 20 is disposed on a light incident side 1016 of the light-emitting device layer 101 in the display panel 10. The backlight 20 may be a common structure in the art.

The display device includes, but is not limited to, a smartphone, a tablet computer, a mobile phone, a video phone, an e-book reader, a laptop PC, a netbook computer, a workstation, a server, a personal digital assistant, a portable multimedia player, a MP3 player, a mobile medical equipment, a camera, a game console, a digital camera, a vehicle navigator, an electronic billboard, an automatic teller machine, a smart bracelet, a smart watch, a virtual reality (VR) device, or a wearable device.

The technical solutions and technical effects of the present disclosure will be described in detail by means of specific examples, comparative examples, and experimental examples. The following examples are only some examples of the present disclosure, and do not specifically limit the present disclosure.

### MATERIAL EXAMPLE 1

This example provides a composition and a film. The composition includes, in parts by weight, the following ingredients: 70 parts of polyurethane acrylate oligomer (resin matrix), 30 parts of dipentaerytritol hexaacrylate (multifunctional reactive monomer), 5 parts of phenylbis (2,4,6-trimethylbenzoyl)-phosphine oxide (initiator), 12.1 parts of gas-phase SiO₂ (scattering particles), 2 parts of additives (BYK-342, commercially available from BYK-Chemie), 150 parts of ethyl acetate (solvent), and 150 parts of methyl isobutyl ketone (solvent, CAS number 108-10-1). In the composition of this example, the ratio of the mass of the scattering particles to the sum of the mass of the resin matrix, the multifunctional reactive monomer, the initiator, and the scattering particles is 10%.

The cross-linked polyacrylic resin oligomer was purchased from Guangzhou Wraio Chemical Materials Co., Ltd., and the product model is FSP59369. The mode diameter of the gas-phase SiO₂ is 3 μm, and the refractive index of the gas-phase SiO₂ is 1.4.

The film was prepared by using the composition of this example. The preparation method of the film includes the steps of providing a substrate, spin-coating the aforementioned composition on one side of the substrate, and then curing to form a film by ultraviolet irradiation, wherein the irradiation intensity of the ultraviolet light is 100 mW/cm², and the irradiation time of the ultraviolet light is 5 s, thereby obtaining a film with an average thickness of 3 μm.

### MATERIAL EXAMPLE 2

This example provides a composition and a film. The composition in this example differs from the composition in Material Example 1 in that the gas-phase SiO₂ is different, and the gas-phase SiO₂ in this example has a mode diameter of 1 μm.

The film in this example differs from the film in Material Example 1 in that the film in this example was prepared by using the composition of this example.

The preparation method of the film in this example was prepared by referring to the preparation method of the film in Material Example 1.

### MATERIAL EXAMPLE 3

This example provides a composition and a film. The composition in this example differs from the composition in Material Example 1 in that the gas-phase SiO₂ is different, and the gas-phase SiO₂ in this example has a mode diameter of 5 μm.

The film in this example differs from the film in Material Example 1 in that the film in this example was prepared by using the composition of this example.

The preparation method of the film in this example was prepared by referring to the preparation method of the film in Material Example 1.

### MATERIAL EXAMPLE 4

This example provides a composition and a film. The composition in this example differs from the composition in Material Example 1 in that the gas-phase SiO₂ is different, and the gas-phase SiO₂ in this example has a mode diameter of 500 nm.

The film in this example differs from the film in Material Example 1 in that the film in this example was prepared by using the composition of this example.

The preparation method of the film in this example was prepared by referring to the preparation method of the film in Material Example 1

### MATERIAL EXAMPLE 5

This example provides a composition and a film. The composition in this example differs from the composition in Material Example 1 in that “12.1 parts of gas-phase SiO₂” is replaced by “23.5 parts of gas-phase SiO₂”, so that the mass of the scattering particles accounts for 18% of the sum of the mass of the resin matrix, the multifunctional reactive monomer, the initiator and the scattering particles.

The film in this example differs from the film in Material Example 1 in that the film in this example was prepared by using the composition of this example.

The preparation method of the film in this example was prepared by referring to the preparation method of the film in Material Example 1.

### MATERIAL EXAMPLE 6

This example provides a composition and a film. The composition in this example differs from the composition in Material Example 1 in that “12.1 parts of gas-phase SiO₂” is replaced by “32 parts of gas-phase SiO₂”, so that the mass of the scattering particles accounts for 23% of the sum of the mass of the resin matrix, the multifunctional reactive monomer, the initiator and the scattering particles.

The film in this example differs from the film in Material Example 1 in that the film in this example was prepared by using the composition of this example.

The preparation method of the film in this example was prepared by referring to the preparation method of the film in Material Example 1.

### MATERIAL EXAMPLE 7

This example provides a composition and a film. The composition in this example differs from the composition in Material Example 1 in that “12.1 parts of gas-phase SiO₂” is replaced by “32 parts of gas-phase SiO₂”, so that the mass of the scattering particles accounts for 23% of the sum of the mass of the resin matrix, the multifunctional reactive monomer, the initiator and the scattering particles. The composition in this example further differs from the composition in Example 1 in that the gas-phase SiO₂ is different, and the gas-phase SiO₂ in this example has a mode diameter of 1 μm.

The film in this example differs from the film in Material Example 1 in that the film in this example was prepared by using the composition of this example.

The preparation method of the film in this example was prepared by referring to the preparation method of the film in Material Example 1.

### MATERIAL EXAMPLE 8

This example provides a composition and a film. The composition in this example differs from the composition in Material Example 1 in that “12.1 parts of gas-phase SiO₂” is replaced by “32 parts of gas-phase SiO₂”, so that the mass of the scattering particles accounts for 23% of the sum of the mass of the resin matrix, the multifunctional reactive monomer, the initiator and the scattering particles. The composition in this example further differs from the composition in Example 1 in that the gas-phase SiO₂ is different, and the gas-phase SiO₂ in this example has a mode diameter of 5 μm.

The film in this example differs from the film in Material Example 1 in that the film in this example was prepared by using the composition of this example.

The preparation method of the film in this example was prepared by referring to the preparation method of the film in Material Example 1.

### MATERIAL EXAMPLE 9

This example provides a composition and a film. The composition in this example differs from the composition in Material Example 1 in that “12.1 parts of gas-phase SiO₂” is replaced by “32 parts of gas-phase SiO₂”, so that the mass of the scattering particles accounts for 23% of the sum of the mass of the resin matrix, the multifunctional reactive monomer, the initiator and the scattering particles. The composition in this example further differs from the composition in Example 1 in that the gas-phase SiO₂ is different, and the gas-phase SiO₂ in this example has a mode diameter of 500 nm.

The film in this example differs from the film in Material Example 1 in that the film in this example was prepared by using the composition of this example.

The preparation method of the film in this example was prepared by referring to the preparation method of the film in Material Example 1.

### MATERIAL EXAMPLE 10

This example provides a composition and a film. The composition in this example differs from the composition in Material Example 1 in that “12.1 parts of gas-phase SiO₂” is replaced by “46 parts of gas-phase SiO₂”, so that the mass of the scattering particles accounts for 30% of the sum of the mass of the resin matrix, the multifunctional reactive monomer, the initiator and the scattering particles.

The film in this example differs from the film in Material Example 1 in that the film in this example was prepared by using the composition of this example.

The preparation method of the film in this example was prepared by referring to the preparation method of the film in Material Example 1.

### MATERIAL EXAMPLE 11

The present example provides a composition and a film. The composition in this example differs from the composition in Material Example 1 in that “12.1 parts of gas-phase SiO₂ (scattering particles)” is replaced by “12.1 parts of polystyrene microspheres (scattering particles)”, wherein the polystyrene microspheres have a mode diameter of 3 μm and a refractive index of 1.59.

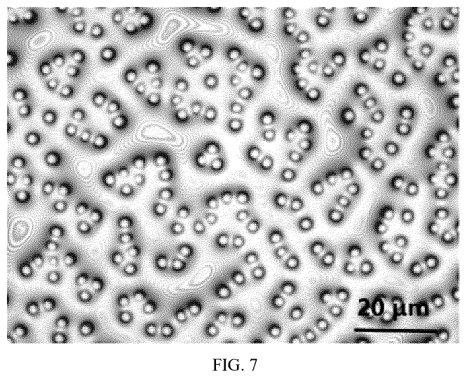

The film in this example differs from the film in Material Example 1 in that the film in this example was prepared by using the composition of this example. FIG. 7 is an ultra-high resolution digital microscope photograph of the surface of the film in this example, and it can be seen from FIG. 7 that the polystyrene microspheres are dispersed in the film in a particle state.

The preparation method of the film in this example was prepared by referring to the preparation method of the film in Material Example 1.

### MATERIAL EXAMPLE 12

The present example provides a composition and a film. The composition in this example differs from the composition in Example 1 in that “12.1 parts of gas-phase SiO₂ (scattering particles)” is replaced by “12.1 parts of TiO₂ (scattering particles)”, wherein the primary mean particle size of TiO₂ is 20 nm, and the mode diameter of aggregates of TiO₂ is 3 μm.

The film in this example differs from the film in Material Example 1 in that the film in this example was prepared by using the composition of this example.

The preparation method of the film in this example was prepared by referring to the preparation method of the film in Material Example 1.

### MATERIAL EXAMPLE 13

The present example provides a composition and a film. The composition in this example differs from the composition in Example 1 in that “12.1 parts of gas-phase SiO₂ (scattering particles)” is replaced by “6.05 parts of TiO₂ (scattering particles)”, wherein the primary mean particle size of TiO₂ is 20 nm, and the mode diameter of aggregates of TiO₂ is 3 μm, so that the mass of the scattering particles accounts for 5% of the sum of the mass of the resin matrix, the multifunctional reactive monomer, the initiator and the scattering particles.

The film in this example differs from the film in Material Example 1 in that the film in this example was prepared by using the composition of this example.

The preparation method of the film in this example was prepared by referring to the preparation method of the film in Material Example 1.

### MATERIAL COMPARATIVE EXAMPLE 1

This comparative example provides a composition and a film. The composition in this comparative example differs from the composition in Material Example 1 in that the gas-phase SiO₂ is different, and the gas-phase SiO₂ in this comparative example has a mode diameter of 200 nm.

The film in this example differs from the film in Material Example 1 in that the film in this example was prepared by using the composition of this example.

The preparation method of the film in this example was prepared by referring to the preparation method of the film in Material Example 1.

### MATERIAL COMPARATIVE EXAMPLE 2

This comparative example provides a composition and a film. The composition in this comparative example differs from the composition in Example 1 in that “12.1 parts of gas-phase SiO₂” is replaced by “32 parts of gas-phase SiO₂”, so that the mass of the scattering particles accounts for 23% of the sum of the mass of the resin matrix, the multifunctional reactive monomer, the initiator and the scattering particles. The composition in this example further differs from the composition in Example 1 in that the gas-phase SiO₂ is different, and the gas-phase SiO₂ in this comparative example has a mode diameter of 200 nm.

The film in this comparative example differs from the film in Material Example 1 in that the film in this comparative example was prepared using the composition of this comparative example.

The preparation method of the film in this comparative example was prepared by referring to the preparation method of the film in Material Example 1.

### DISPLAY DEVICE EXAMPLE 1

This example provides a display device. As shown in FIG. 6, the display device includes a display panel 10 and a backlight 20. The backlight 20 is disposed on a light incident side 1016 of a light-emitting device layer 101 in the display panel 10, and the backlight 20 is a white backlight.

The display panel 10 is a liquid crystal display panel. As shown in FIGS. 2 to 5, the display panel 10 includes a light-emitting device layer 101, a first polarizer 102 and a wide-viewing film 103 that are sequentially disposed. The light-emitting device layer 101 includes a second polarizer 1012, an array substrate 1013, a liquid crystal layer 1014, and a color filter substrate 1015 that are sequentially disposed. The light-emitting device layer 101 includes a plurality of pixels distributed in an array, each pixel includes a red sub-pixel, a blue sub-pixel, and a green sub-pixel.

In the display panel of this embodiment, a wide-viewing film 103 is added to the first standard display panel. The first standard display panel has a four-domain pixel structure with a transmittance of 5.3%, a contrast of 5000:1, and CESI 0.03 of 70° (degrees), 65 inches, and 4K resolution.

Continuing to refer to FIG. 2, the wide-viewing film 103 is composed of an adhesive layer 1032, a substrate layer 1031, and a diffusion layer 1033, which are sequentially stacked. The material of the adhesive layer 1032 is an ultraviolet curing adhesive, and the average thickness of the adhesive layer 1032 is 20 μm. The material of the substrate layer 1031 is polyethylene terephthalate, and the average thickness of the substrate layer 1031 is 60 μm. The diffusion layer 1033 is the film obtained in Material Example 1, and correspondingly, the average thickness of the diffusion layer 1033 is 3 μm.

### DISPLAY DEVICE EXAMPLE 2

This example provides a display device. The display device in this example differs from the display device in Display Device Example 1 in that the structure of the diffusion layer is different, and the diffusion layer in this example is the film obtained in Material Example 2 .

### DISPLAY DEVICE EXAMPLE 3

This example provides a display device. The display device in this example differs from the display device in Display Device Example 1 in that the structure of the diffusion layer is different, and the diffusion layer in this example is the film obtained in Material Example 3.

### DISPLAY DEVICE EXAMPLE 4

This example provides a display device. The display device in this example differs from the display device in Display Device Example 1 in that the structure of the diffusion layer is different, and the diffusion layer in this example is the film obtained in Material Example 4.

### DISPLAY DEVICE EXAMPLE 5

This example provides a display device. The display device in this example differs from the display device in Display Device Example 1 in that the structure of the diffusion layer is different, and the diffusion layer in this example is the film obtained in Material Example 5.

### DISPLAY DEVICE EXAMPLE 6

This example provides a display device. The display device in this example differs from the display device in Display Device Example 1 in that the structure of the diffusion layer is different, and the diffusion layer in this example is the film obtained in Material Example 6.

### DISPLAY DEVICE EXAMPLE 7

This example provides a display device. The display device in this example differs from the display device in Display Device Example 1 in that the structure of the diffusion layer is different, and the diffusion layer in this example is the film obtained in Material Example 7.

### DISPLAY DEVICE EXAMPLE 8

This example provides a display device. The display device in this example differs from the display device in Display Device Example 1 in that the structure of the diffusion layer is different, and the diffusion layer in this example is the film obtained in Material Example 8.

### DISPLAY DEVICE EXAMPLE 9

This example provides a display device. The display device in this example differs from the display device in Display Device Example 1 in that the structure of the diffusion layer is different, and the diffusion layer in this example is the film obtained in Material Example 9.

### DISPLAY DEVICE EXAMPLE 10

This example provides a display device. The display device in this example differs from the display device in Display Device Example 1 in that the structure of the diffusion layer is different, and the diffusion layer in this example is the film obtained in Material Example 10.

### DISPLAY DEVICE EXAMPLE 11

This example provides a display device. The display device in this example differs from the display device in Display Device Example 1 in that the structure of the diffusion layer is different, and the diffusion layer in this example is the film obtained in Material Example 15.

### DISPLAY DEVICE EXAMPLE 12

This example provides a display device. The display device in this example differs from the display device in Display Device Example 1 in that the structure of the diffusion layer is different, and the diffusion layer in this example is the film obtained in Material Example 16.

### DISPLAY DEVICE EXAMPLE 13

This example provides a display device. The display device in this example differs from the display device in Display Device Example 1 in that the structure of the diffusion layer is different, and the diffusion layer in this example is the film obtained in Material Example 17.

### DISPLAY DEVICE COMPARATIVE EXAMPLE 1

This example provides a display device. The display device in this example differs from the display device in Display Device Example 1 in that the structure of the diffusion layer is different, and the diffusion layer in this example is the film obtained in Material Comparative Example 1.

### DISPLAY DEVICE COMPARATIVE EXAMPLE 2

This example provides a display device. The display device in this example differs from the display device in Display Device Example 1 in that the structure of the diffusion layer is different, and the diffusion layer in this example is the film obtained in Material Comparative Example 2.

EXPERIMENTAL EXAMPLE 1

Under the same testing conditions, the performance of the display devices in Display Device Examples 1 to 13, Display Device Comparative Example 1, and Display Device Comparative Example 2 was tested.

The brightness of the display panel in the display device is measured by using KONICA MINOLTA CS-2000 as a test instrument. The testing method is as follows: placing the display device in a dark room, and testing the brightness in the direction parallel to the normal of the display panel to obtain the brightness of 255 grayscale images of the display panel. The formula for calculating the transmittance is: transmittance (%)=255 grayscale image brightness of the display panel/brightness of the backlight×100%. The formula for calculating the contrast is: contrast=255 grayscale image brightness of the display panel/0 grayscale brightness of the display panel.

The R/G/B grayscale values corresponding to the nine characteristic color images tested by CESI chromaticity viewable angle are as follows, with R representing a red component, G representing a green component, and B representing a blue component. For the red image: R=166, G=62, and B=68; for the blue image: R=64, G=69, and B=145; for the dark skin image: R=115, G=87, and B=74; for the light skin image: R=183, G=145, and B=128; for the green image: R=76, G=143, and B=79; for the yellow image: B=214, G=187, and B=43; for the magenta image: R=177, G=690, and B=143; for the cyan image: R=23, G=130, and B=154; and for the gray image: R=121, G=121, and B=120. The tristimulus values XYZ in the CIE 1931 color space of each image are respectively measured. The angle range of the test direction along the horizontal direction of the display panel and the normal of the display panel ranges from −60° (degrees) to +60° (degrees). The tristimulus values XYZ are converted to Lu′v′ color space, and the formula for converting is as follows:

$${u}^{′} = \frac{4 X}{X + 15 Y + 3 Z}$$

$${v}^{′} = \frac{9 Y}{X + 15 Y + 3 Z}$$

Δuv=\sqrt{(u′−u′⁰)²+(v′−v′₀)²} is defined as the color difference value at this angle, wherein u₀ and v₀ are respectively the u′ and v′ values when the measurement direction is 0 degrees from the normal. CESI 0.03 is the angle at which the average of the nine test images Δuv is 0.03.

In addition, the glossiness and haze of the wide viewing angle film of the display devices in Display Device Examples 1 to 13, Display Device Comparative Example 1, and Display Device Comparative Example 2 are respectively tested. It should be noted that the wide viewing angle films of each display device are detected separately, that is, the wide viewing angle films that are not adhered to the surface of the first polarizer are detected, and the gloss and haze test data do not include the glossiness and haze of the first polarizer.

The test method of the haze of the wide viewing angle films is carried out with reference to the measurement of the haze of the transparent materials in ISO 14782. The test method is carried out with reference to the measurement of the haze of the transparent materials in ISO 14782. The test instrument is HAZE Meter/NDH 7000 of NIPPON DENSHOKU, which detects and obtains the haze center value of the wide viewing angle film.

The method for testing the glossiness of the wide viewing angle film is as follows: using Multi Gloss 268A of KONICA MINOLTA as the test instrument and conducting the test based on 60° (degrees).

TABLE 5

| | Transmittance | | Chromaticity viewing | Brightness | | Haze center |
|---|---|---|---|---|---|---|
| Number | (%) | Contrast | angle (CESI 0.03) | (Nit) | Glossiness | value |
| Display Device Example 1 | 6.87 | 4613:1 | 74° | 423 | 16.8% | 49% |
| Display Device Example 2 | 6.85 | 4573:1 | 72° | 432 | 17.2% | 50% |
| Display Device Example 3 | 6.47 | 3956:1 | 74° | 401 | 19.2% | 65% |
| Display Device example 4 | 6.92 | 5483:1 | 64° | 442 | 37.6% | 23% |
| Display Device Example 5 | 6.47 | 3331:1 | 84° | 391 | 7.3% | 78% |
| Display Device Example 6 | 6.31 | 2056:1 | 112° | 369 | 6.3% | 81% |
| Display Device example 7 | 6.24 | 2187:1 | 114° | 358 | 6.2% | 84% |
| Display Device example 8 | 5.89 | 1459:1 | 108° | 317 | 5.8% | 88% |
| Display Device Example 9 | 6.78 | 4987:1 | 76° | 426 | 18.5% | 43% |
| Display Device example 10 | 5.36 | 1428:1 | 120° | 296 | 5.4% | 90% |
| Display Device Example 11 | 6.74 | 3569:1 | 74° | 415 | 23.1% | 52% |
| Display device example 12 | 6.14 | 1755:1 | 82° | 398 | 15.1% | 46% |
| Display Device Example 13 | 5.99 | 1755:1 | 82° | 368 | 12.1% | 73% |
| Display Device | 7 | 6203:1 | 62° | 430 | 98.6% | 2% |
| Comparative Example 1 | | | | | | |
| Display Device | 6.9 | 6198:1 | 64° | 428 | 97.9% | 2% |
| Comparative Example 2 | | | | | | |

In addition, the chromaticity viewing angles Δuv30° and Δuv45° of the display devices in the display device Examples 1 to 10, the display device Comparative Example 1, and the display device Comparative Example 2 were calculated. For each display device, the chrominance angle Δuv30° is an average value of Δuv30° of the first grayscale image and Δuv30° of the second grayscale image, and the chrominance angle Δuv45° is an average value of Δuv45° of the first grayscale image and Δuv45° of the second grayscale image, wherein the grayscale RGB of the first grayscale image is 64, 69, 145, and the grayscale RGB of the second grayscale image is 166, 62, 68.

The formula for calculating Δuv30° for each grayscale image is as follows:

$$u = \frac{4 x}{- 2 x + 12 y + 3}$$

$$v = \frac{9 y}{- 2 x + 12 y + 3}$$

$$Δ u = {u}_{0} - {u}_{30}$$

$$Δ v = {v}_{0} - {v}_{30}$$

$$Δ uv = \sqrt{Δ {u}^{2} + Δ {v}^{2}}$$

wherein x and y are the abscissa and ordinate values of the color coordinate, respectively, and U₃₀ and V₃₀ are the corresponding values of u and v at 30 degrees. It should be understood that the formula for calculating Δuv45° is to replace the corresponding u30 with u45, and to replace v30 with v45 in the formula for calculating Δuv30°.

The test results are shown in Table 6 below:

TABLE 6

| Number | Δuv30° | Δuv45° |
|---|---|---|
| Display Device Example 1 | 0.049 | 0.069 |
| Display Device Example 2 | 0.052 | 0.072 |
| Display Device Example 3 | 0.054 | 0.076 |
| Display device example 4 | 0.058 | 0.078 |
| Display Device Example 5 | 0.042 | 0.066 |
| Display Device Example 6 | 0.04 | 0.062 |
| Display device example 7 | 0.043 | 0.064 |
| Display device example 8 | 0.046 | 0.066 |
| Display Device Example 9 | 0.048 | 0.068 |
| Display device example 10 | 0.038 | 0.06 |
| Display device Comparative Example 1 | 0.067 | 0.083 |
| Display device Comparative Example 2 | 0.058 | 0.079 |

As can be seen from Tables 5 and 6, compared with the display devices in Display Device Comparative Example 1 and Display Device Comparative Example 2, the comprehensive performance of the display devices in Display Device Examples 1 to 13 is more advantageous. Compared with the display devices in Display Device Comparative Example 1 and Display Device Comparative Example 2, the display devices in Display Device Example 1 to Display Device Example 13 have a better improvement effect on the color shift problem and have good transmittance, resolution, glossiness and haze. In Display Device Comparative Example 1 and Display Device Comparative Example 2, the glossiness of the display devices is too high, the haze center value is too low, and the CESI 0.03 is low. This shows that the scattering particle in the diffusion layer of the display device has a mode diameter ranging from 500 nm to 5 μm, which has a stronger scattering effect, and exhibits a lower glossiness and a higher haze, thus having better chromaticity viewing angle.

In order to further improve the scattering effect, transmittance and contrast, the ratio of the mass of the scattering particles to the sum of the mass of the resin matrix, the multifunctional reactive monomer, the initiator and the scattering particles ranges from 18% to 23%, which can further improve the color shift problem of display panel in display device. The reason is that as the content of scattering particles increases, the scattering effect of the diffusion layer becomes stronger. However, due to the influence of scattering, the display panel in the bright state has a problem of partial light loss, and the display panel in the dark state has a problem of light leakage, which causes the transmittance and contrast of the display panel to decrease.

In addition, for the display panels of the display devices in Display Device Example 1 and Display Device Example 11, it was detected that the wide viewing angle film of Display Device Example 1 has an outer haze of 12%, and an inner haze of 45%, the wide viewing angle film of Display Device Example 11 has an outer haze of 50%, and an inner haze of 4%. It can be understood that the higher the outer haze, the stronger the anti-glare effect can be formed on the surface of the wide viewing angle film, and that the higher the inner haze, the greater the reduction in contrast of the display panel.

In the above-mentioned examples, the description of each example has its own focus. For parts that are not described in detail in an example, please refer to related descriptions of other examples.

In view of the foregoing, the composition, film, display panel, and display device provided in examples of the present disclosure have been described in detail above, and the principles and embodiments of the present disclosure are described by using specific examples herein. Descriptions of the above examples are merely intended to help understand the technical solutions and core ideas of the present disclosure. A person with ordinary skill in the art should understand that various modifications may still be made to the technical solutions described in the foregoing examples, or equivalents may be made to some of the technical features therein. These modifications or substitutions do not depart the essence of the corresponding technical solutions from the scope of the technical solutions of the examples of the present disclosure.

What is claimed is:

1. A composition comprising, in parts by weight, the following ingredients:
50 parts to 100 parts of a resin matrix;
20 parts to 100 parts of a multifunctional reactive monomer;
1 part to 10 parts of an initiator;
5 parts to 30 parts of scattering particles;
100 parts to 500 parts of a solvent; and
1 part to 10 parts of additives;
wherein each of the scattering particles has a mode diameter ranging from 500 nm to 5 μm.

2. The composition according to claim 1, wherein a ratio of a mass of the scattering particles to a sum of a mass of the resin matrix, the multifunctional reactive monomer, the initiator, and the scattering particles ranges from 10% to 30%; and/or
a refractive index of the scattering particles ranges from 1.3 to 1.7; and/or
the scattering particles are selected from spherical solid particles or mesoporous particles; and/or
an average particle size of the scattering particles and/or an average particle size of an aggregate of the scattering particles ranges from 1 μm to 3 μm; and/or
the scattering particles are selected from one or more of inorganic scattering particles and the organic scattering particles, the inorganic scattering particles are selected from one or more of SiO₂, TiO₂, ZrO₂, Al₂O₃, and CaCO₃, and/or the organic scattering particles are selected from one or more of polystyrene, polymethyl methacrylate, and polybutyl methacrylate.

3. The composition according to claim 2, wherein the ratio of the mass of the scattering particles to the sum of the mass of the resin matrix, the multifunctional reactive monomer, the initiator, and the scattering particles ranges from 18% to 23%; and/or
the refractive index of the scattering particles ranges from 1.35 to 1.50.

4. The composition according to claim 1, wherein the resin matrix is selected from one or more of acrylic resin, epoxy resin, and polyurethane resin; and/or
a refractive index of the resin matrix ranges from 1.3 to 1.7; and/or
an absolute value of a difference between the refractive index of the resin matrix and the refractive index of the scattering particles is not more than 0.1; and/or
a degree of polymerization of the resin matrix ranges from 10 to 100; and/or
a weight average molecular weight of the resin matrix ranges from 1000 to 30000; and/or
the multifunctional reactive monomer is selected from one or more of an acrylate monomer, an unsaturated olefin monomer, and an epoxy monomer; and/or
the initiator is selected from one or more of a peroxide initiator, an azo initiator, an acylphosphine oxide photoinitiator, and an amine initiator; and/or
the solvent is selected from one or more of an ester compound, a ketone compound, an alcohol compound, and an ether compound; and/or
the additives are selected from one or more of leveling agents, defoaming agents, dispersants, antifouling additives, antioxidants, and ultraviolet absorbers.

5. The composition according to claim 2, wherein the resin matrix is selected from one or more of acrylic resin, epoxy resin, and polyurethane resin; and/or
a refractive index of the resin matrix ranges from 1.3 to 1.7; and/or
an absolute value of a difference between the refractive index of the resin matrix and the refractive index of the scattering particles is not more than 0.1; and/or
a degree of polymerization of the resin matrix ranges from 10 to 100; and/or
a weight average molecular weight of the resin matrix ranges from 1000 to 30000; and/or
the multifunctional reactive monomer is selected from one or more of an acrylate monomer, an unsaturated olefin monomer, and an epoxy monomer; and/or
the initiator is selected from one or more of a peroxide initiator, an azo initiator, an acylphosphine oxide photoinitiator, and an amine initiator; and/or
the solvent is selected from one or more of an ester compound, a ketone compound, an alcohol compound, and an ether compound; and/or
the additives are selected from one or more of leveling agents, defoaming agents, dispersants, antifouling additives, antioxidants, and ultraviolet absorbers.

6. The composition according to claim 3, wherein the resin matrix is selected from one or more of acrylic resin, epoxy resin, and polyurethane resin; and/or
a refractive index of the resin matrix ranges from 1.3 to 1.7; and/or
an absolute value of a difference between the refractive index of the resin matrix and the refractive index of the scattering particles is not more than 0.1; and/or
a degree of polymerization of the resin matrix ranges from 10 to 100; and/or
a weight average molecular weight of the resin matrix ranges from 1000 to 30000; and/or
the multifunctional reactive monomer is selected from one or more of an acrylate monomer, an unsaturated olefin monomer, and an epoxy monomer; and/or
the initiator is selected from one or more of a peroxide initiator, an azo initiator, an acylphosphine oxide photoinitiator, and an amine initiator; and/or
the solvent is selected from one or more of an ester compound, a ketone compound, an alcohol compound, and an ether compound; and/or
the additives are selected from one or more of leveling agents, defoaming agents, dispersants, antifouling additives, antioxidants, and ultraviolet absorbers.

7. The composition according to claim 4, wherein the acrylate monomer is selected from one or more of pentaerythritol triacrylate, dipentaerytritol hexaacrylate, ditrimethylolpropane tetraacrylate, isoboryl acrylate and 1,6-hexane diol diacrylate, and/or the unsaturated olefin monomer is selected from one or more of dodecenyl succinic anhydride, dodecyl vinyl ether, octadecyl vinyl ether, and 1,4-cyclohexanedimethanol divinyl ether, and/or the epoxy monomer is selected from one or more of triethylene glycol diglycidyl ether, glycerol triglycidyl ether, and pentaerythritol tetraglycidyl ether; and/or
the peroxy compound initiator is selected from one or more of dibenzoyl peroxide, lauroyl peroxide, tert-butyl peroxybenzoate, tert-butyl peroxypentanoate and t-hexyl peroxy-2-ethyl hexanoate, and/or the azo initiator is selected from one or more of azobisisobutyronitrile and azobisisoheptanenitrile, and/or the acylphosphine oxide photoinitiator is selected from one or more of 2,4,6-(trimethylbenzoyl)-diphenylphosphine oxide and phenylbis (2,4,6-trimethylbenzoyl)-phosphine oxide, and/or the amine initiator is selected from ethyl 4-dimethylaminobenzoate; and/or
the ester compound is selected from one or more of ethyl acetate, methyl acetate, ethyl formate, and propyl acetate, and/or the ketone compound is selected from one or more of acetone, methyl isobutyl ketone, and butanone, and/or the alcohol compound is selected from one or more of methanol, ethanol, propanol, butanol, and pentanol, and/or the ether compound is selected from one or more of methyl ether, ethyl ether, propyl ether, butyl ether, and pentyl ether.

8. The composition according to claim 5, wherein the acrylate monomer is selected from one or more of pentaerythritol triacrylate, dipentaerytritol hexaacrylate, ditrimethylolpropane tetraacrylate, isoboryl acrylate and 1,6-hexane diol diacrylate, and/or the unsaturated olefin monomer is selected from one or more of dodecenyl succinic anhydride, dodecyl vinyl ether, octadecyl vinyl ether, and 1,4-cyclohexanedimethanol divinyl ether, and/or the epoxy monomer is selected from one or more of triethylene glycol diglycidyl ether, glycerol triglycidyl ether, and pentaerythritol tetraglycidyl ether; and/or
the peroxy compound initiator is selected from one or more of dibenzoyl peroxide, lauroyl peroxide, tert-butyl peroxybenzoate, tert-butyl peroxypentanoate and t-hexyl peroxy-2-ethyl hexanoate, and/or the azo initiator is selected from one or more of azobisisobutyronitrile and azobisisoheptanenitrile, and/or the acylphosphine oxide photoinitiator is selected from one or more of 2,4,6-(trimethylbenzoyl)-diphenylphosphine oxide and phenylbis (2,4,6-trimethylbenzoyl)-phosphine oxide, and/or the amine initiator is selected from ethyl 4-dimethylaminobenzoate; and/or
the ester compound is selected from one or more of ethyl acetate, methyl acetate, ethyl formate, and propyl acetate, and/or the ketone compound is selected from one or more of acetone, methyl isobutyl ketone, and butanone, and/or the alcohol compound is selected from one or more of methanol, ethanol, propanol, butanol, and pentanol, and/or the ether compound is selected from one or more of methyl ether, ethyl ether, propyl ether, butyl ether, and pentyl ether.

9. The composition according to claim 6, wherein the acrylate monomer is selected from one or more of pentaerythritol triacrylate, dipentaerytritol hexaacrylate, ditrimethylolpropane tetraacrylate, isoboryl acrylate and 1,6-hexane diol diacrylate, and/or the unsaturated olefin monomer is selected from one or more of dodecenyl succinic anhydride, dodecyl vinyl ether, octadecyl vinyl ether, and 1,4-cyclohexanedimethanol divinyl ether, and/or the epoxy monomer is selected from one or more of triethylene glycol diglycidyl ether, glycerol triglycidyl ether, and pentaerythritol tetraglycidyl ether; and/or
the peroxy compound initiator is selected from one or more of dibenzoyl peroxide, lauroyl peroxide, tert-butyl peroxybenzoate, tert-butyl peroxypentanoate and t-hexyl peroxy-2-ethyl hexanoate, and/or the azo initiator is selected from one or more of azobisisobutyronitrile and azobisisoheptanenitrile, and/or the acylphosphine oxide photoinitiator is selected from one or more of 2,4,6-(trimethylbenzoyl)-diphenylphosphine oxide and phenylbis (2,4,6-trimethylbenzoyl)-phosphine oxide, and/or the amine initiator is selected from ethyl 4-dimethylaminobenzoate; and/or
the ester compound is selected from one or more of ethyl acetate, methyl acetate, ethyl formate, and propyl acetate, and/or the ketone compound is selected from one or more of acetone, methyl isobutyl ketone, and butanone, and/or the alcohol compound is selected from one or more of methanol, ethanol, propanol, butanol, and pentanol, and/or the ether compound is selected from one or more of methyl ether, ethyl ether, propyl ether, butyl ether, and pentyl ether.

10. A film prepared by subjecting the composition according to claim 1 to a thermo-curing treatment and/or a photo-curing treatment.

11. The film according to claim 10, wherein the film comprises a resin portion, and at least a part of the scattering particles protrudes from a surface of the resin portion; and/or
an average thickness of the film ranges from 1 μm to 5 μm; and/or
a mass of the scattering particles accounts for 10% to 30% of a total mass of the film.

12. The film according to claim 10, wherein the film comprises a resin portion, and at least a part of the scattering particles protrudes from a surface of the resin portion; and/or an average thickness of the film ranges from 1 μm to 5 μm; and/or a mass of the scattering particles accounts for 18% to 23% of a total mass of the film.

13. The film according to claim 10, wherein the film comprises a resin portion, and at least a part of the scattering particles protrudes from a surface of the resin portion; and/or
an average thickness of the film ranges from 2 μm to 4 μm; and/or
a mass of the scattering particles accounts for 10% to 30% of a total mass of the film.

14. The film according to claim 10, wherein the film comprises a resin portion, and at least a part of the scattering particles protrudes from a surface of the resin portion; and/or
an average thickness of the film ranges from 2 μm to 4 μm; and/or
a mass of the scattering particles accounts for 18% to 23% of a total mass of the film.

15. A display panel, comprising:
a light-emitting device layer comprising a light incident side and a light outgoing side oppositely disposed; and
a wide-viewing film disposed on the light outgoing side of the light-emitting device layer;
wherein the wide-viewing film comprises a diffusion layer, and the diffusion layer is the film according to claim 10.

16. The display panel according to claim 15, further comprising a first polarizer disposed between the light-emitting device layer and the wide-viewing film; or, the display panel further comprising a polarizing film and a and a compensation film that are stacked, the polarizing film being disposed between the light-emitting device layer and the wide-viewing film, and the compensation film being disposed on one side of the polarizing film away from the wide-viewing film; and/or
the wide-viewing film further comprising a substrate layer disposed on one side of the diffusion layer close to the light-emitting device layer, and the substrate layer being selected from transparent polymers; and/or
the light-emitting device layer comprising a liquid crystal layer, an array substrate, a color filter substrate and a second polarizer, the array substrate and the color filter substrate being disposed oppositely and respectively located on both sides of the liquid crystal layer, the second polarizer being disposed on one side of the array substrate away from the liquid crystal layer, and the wide-viewing film being located on one side of the color filter substrate away from the liquid crystal layer; or, the light-emitting device layer comprising a plurality of light-emitting diodes disposed in an array; and/or
the display panel comprising a multi-domain pixel structure.

17. The display panel according to claim 16, wherein the transparent polymers are selected from one or more of ethylene phthalate, polymethyl methacrylate, cellulose triacetate, and cyclic olefin polymers.

18. The display panel according to claim 16, wherein the display panel has a four-domain pixel structure or an eight-domain pixel structure.

19. A display device comprising:
the display panel according to claim 15; and
a backlight disposed on the light incident side of the light-emitting device layer in the display panel.
